(19) United States
(12) Patent Application Publication
(10) Pub. No.: US 2013/0337625 A1
(43) Pub. Date: Dec. 19, 2013

(54) METHOD FOR MANUFACTURING SEMICONDUCTOR DEVICE

(71) Applicant: Elpida Memory, Inc., Tokyo (JP)

(72) Inventor: Naonori FUJIWARA, Tokyo (JP)

(21) Appl. No.: 13/913,892

(22) Filed: Jun. 10, 2013

(30) Foreign Application Priority Data
Jun. 15, 2012 (JP) 2012-136011
Oct. 5, 2012 (JP) 2012-222886

(51) Int. Cl. H01L 21/02; H01L 49/02

(52) U.S. Cl. CPC H01L 21/02271; H01L 28/40
USPC 438/381; 438/785

(57) ABSTRACT

The present invention provides a method for manufacturing a semiconductor device including a metal compound film formation process based on an atomic layer deposition (ALD) with repeating a plurality of cycles in which a supply time of a metallic source gas at the first time of the cycles is longer than a supply time of the source gas at the second time or later of the cycles, the ALD including, as one cycle, supplying the metallic source gas to adsorb a metallic source onto a foundation; purging the metallic source gas from a film-forming space; supplying a reactant gas to convert the metallic source into a corresponding metal compound; and purging the reactant gas.

### BACKGROUND OF THE INVENTION

1. Field of the Invention

The present invention relates to a method for manufacturing a semiconductor device. More particularly, the invention relates to the method including a film-forming by an atomic layer deposition.

2. Description of the Related Art

DRAMs are used in computers and other electronic equipment as semiconductor memory devices capable of high-speed operation. A memory cell array and a peripheral circuit for driving the memory cell array primarily constitute a DRAM. The memory cell array includes a plurality of unit components which are disposed into a matrix state and each of which is composed of one switching transistor and one capacitor.

Like in other semiconductor devices, efforts are being made to miniaturize individual cells in the DRAM, in order to meet high integration requirements. As a result, an allowable planar area available to form a capacitor has reduced, thus causing difficulty in securing capacity required for a storage device. As measures against this problem, studies have been made of, for example, the three-dimensional formation of an electrode structure, the construction of upper and lower electrodes from a metal material (MIM structure), and the increase of the dielectric constant of a capacitor insulating film. Consequently, the three-dimensional formation of an electrode structure is essential for a DRAM in a domain where the minimum feature size (F value) used as the standard index of a technological level is no larger than 70 nm. Upper and lower electrodes constructed from a metal material are already in practical use. Accordingly, the further characteristic improvements of capacitors based on these technological developments are less promising. The mainstream of further miniaturization in the future is the last remaining study on improvements in the characteristics of a capacitor by increasing the dielectric constant of a capacitor insulating film.

Characteristic requirements for capacitors of a semiconductor memory device include:
(1) Availability of large capacitance, i.e., a high dielectric constant (small EOT to be described later); and
(2) Small leakage current of a capacitor insulating film.
   Generally speaking, however, a high-dielectric constant film having a large dielectric constant exhibits the characteristics of being low in insulation breakdown resistance and large in leakage current. That is, the increase of dielectric constants and the decrease of leakage currents are in a trade-off relationship. Development of a capacitor structure the leakage current of which does not increase even if a high-dielectric constant film is used and which is superior in reliability and a technique to manufacture the capacitor structure are desired in order to realize further miniaturized memory cells.

Under such circumstances, a capacitor having an MIM structure, for example, a titanium nitride (TiN)/zirconium oxide (ZrO₂, which is hereinafter described as ZrO)/TiN structure, has come to be used as a capacitor of a DRAM.

Atomic layer deposition (ALD) is used exclusively as a method for forming a dielectric film with excellent film thickness controllability by the three-dimensional formation of an electrode structure.

As an ALD method for ZrO films, JP2011-171566A, for example, discloses repeating a cycle of source gas supply/purge/oxidizing gas (ozone (O₃) gas) supply/purge using a first exhaust pipe for emitting a source gas and a second exhaust pipe for emitting a purge gas to form ZrO films.

In capacitor dielectric film deposition based on a conventional ALD method, a cycle of source gas supply/purge/oxidizing gas supply/purge is defined as one cycle and several tens of cycles are repeated to form a uniform film of the same degree in each cycle.

Here, the inventor has found out the following: when an attempt is made to form a zirconium oxide (ZrO) film on titanium nitride (TiN) of a lower electrode, a Zr raw material is less likely to adsorb onto TiN in the first cycle in which the ZrO film is first formed on TiN, in comparison with the second cycle or later in which the ZrO film is already formed, and therefore, the supply time of a Zr source gas needs to be lengthened in order to increase adsorption probability. On the other hand, the inventor has discovered a problem of constituents (for example, carbon) contained in the source gas being introduced into the ZrO film as impurities if the supply time of the Zr source gas is lengthened, thus increasing the leakage current of a capacitor dielectric film.

### SUMMARY

The present invention provides a method for forming a film with a reduced amount of impurity by atomic layer deposition.

That is, according to one embodiment of the present invention, there is provided a method for manufacturing a semiconductor device comprising a metal compound film formation process based on an atomic layer deposition, the atomic layer deposition including, as one cycle:

supplying a source gas containing a metallic source to adsorb the metallic source onto a foundation;

purging the source gas;

supplying a reactant gas to convert the metallic source into a corresponding metal compound; and

purging the reactant gas,

wherein a supply time of the source gas in a first cycle is longer than a supply time of the source gas in a second cycle or later.

According to another embodiment of the present invention, there is provided a method for manufacturing semiconductor device comprising an insulating film formation process by an atomic layer deposition method, wherein the atomic layer deposition method includes supplying a source gas in forming the insulating film,

wherein the source gas in a first cycle is supplied for a first supplying time, thereafter the source gas is supplied for a second supplying time, and wherein the first supplying time is longer than the second supplying time.

In the present invention, a desired atomic layer is uniformly formed by an atomic layer deposition (ALD) method with setting a supply time of a source gas at the first time of cycles in the ALD method to deposit a first layer on a material inferior in adsorption ability to be longer than the supply time of the source gas at the second time or later of the cycles to deposit a second layer or another layer on or over the first layer. As the result of the first layer being uniform, atomic layers can be formed also uniformly in the second cycle or later even if the supply time of the source gas is made shorter than the supply time of the source gas in the first cycle, thus decreasing the probability of impurities being introduced into films. A capacitor superior in leakage characteristics can be provided when the method is used for a formation of a capacitor dielectric film of the capacitor.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic view illustrating a film-forming sequence by an ALD method to form a ZrO film of a conventional example;

FIG. 2 is a graph illustrating the relationship between the supply time of a Zr source gas and the number of fail bits per chip in a capacitor dielectric film leak test according to the conventional example;

FIG. 3 is a schematic view illustrating a film-forming sequence by an ALD method to form a ZrO film according to one exemplary embodiment of the present invention;

FIG. 4A is a graph illustrating the relationship between the supply time of a Zr source gas (TEMAZ) in the second cycle or later and the number of fail bits per chip in a capacitor dielectric film leak test according to one exemplary embodiment of the present invention;

FIG. 4B is a graph illustrating the relationship between the supply time of a Zr source gas (Zr(NMe₂)₃Cp) in the second cycle or later and the number of fail bits per chip in a capacitor dielectric film leak test according to one exemplary embodiment of the present invention;

FIG. 5 is a graph illustrating the relationship between the supply time of a Zr source gas (TEMAZ) in the first cycle and the increase ratio of fail bits per chip in a capacitor dielectric film leak test according to one exemplary embodiment of the present invention;

FIG. 6 is a graph illustrating the relationship between the supply time of a Zr source gas (Zr(NMe₂)₃Cp) in the first cycle and the increase ratio of fail bits per chip in a capacitor dielectric film leak test according to one exemplary embodiment of the present invention;

FIG. 7 is a plan view schematically illustrating a memory cell region of DRAM device 100 according to one exemplary embodiment of the present invention;

FIGS. 8A and 8B are schematic cross-sectional views of DRAM device 100 according to one exemplary embodiment of the present invention, wherein FIG. 8A illustrates the A-A′ cross section of FIG. 7 and FIG. 8B illustrates the B-B′ cross section of FIG. 7; and

FIG. 9A to FIG. 30B are cross-sectional process diagrams used to describe a method for manufacturing DRAM device 100 according to one exemplary embodiment of the present invention, wherein each figure suffixed with A corresponds to the A-A′ cross section of FIG. 7 and each figure suffixed with B corresponds to the B-B′ cross section of FIG. 7.

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

First, problems in the related art will be described.

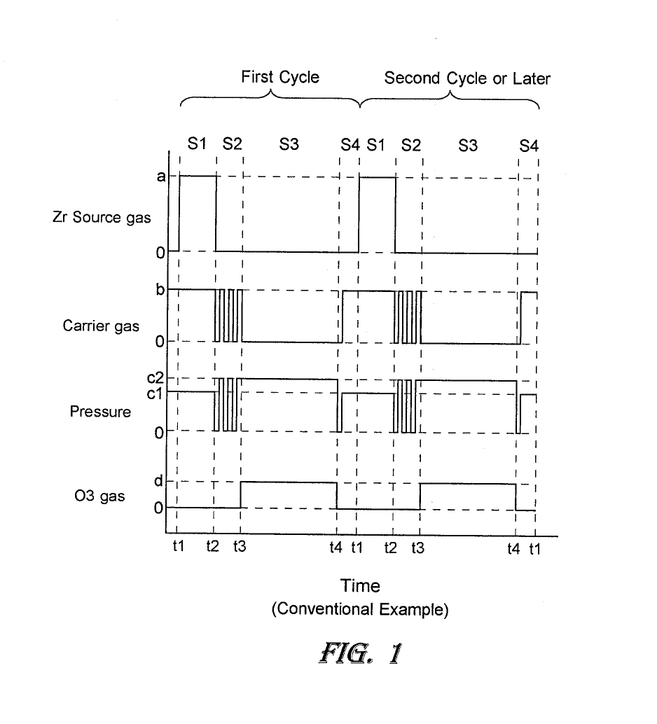

FIG. 1 illustrates a film-forming sequence by an ALD method to form a ZrO film of a conventional example. The film-forming sequence is defined as the repetition of a plurality of cycles, each of the cycles including a Zr source gas supplying step (time t1→t2: S1), a purge step (time t2→t3: S2), an oxidation step (time t3→t4: S3), and a purge step (time t4→t1: S4), wherein a first cycle that means essentially the first time of the cycles and a second cycle that means essentially the second time of the cycles or later are the same.

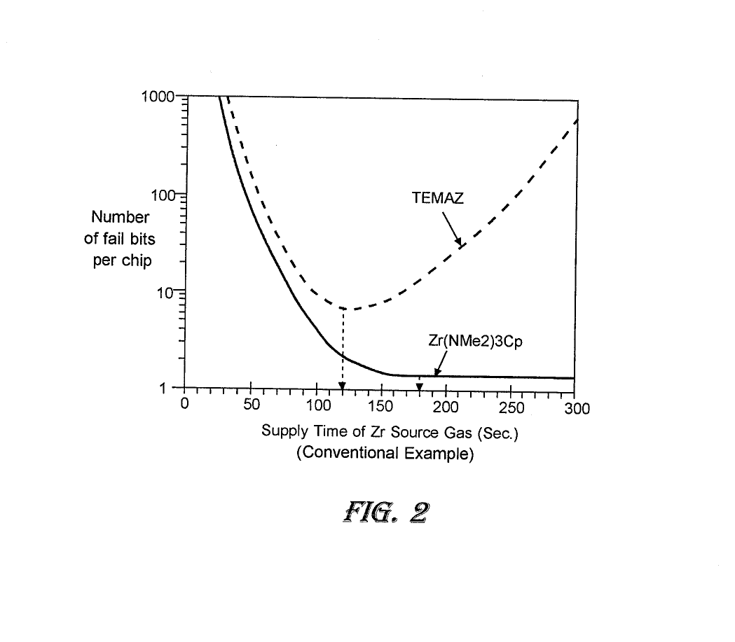

FIG. 2 is a graph illustrating the relationship between a supply time of a Zr source gas and the number of fail bits per 1 chip in a capacitor dielectric film leak test according to the conventional example. FIG. 2 illustrates a case in which a ZrO film is formed on a lower TiN electrode. The figure also illustrates a case in which widely used tetrakis(ethyl-methyl-amino) zirconium ((CH₃)(C₂H₅)N)₄Zr, which is hereinafter referred to as TEMAZ) and expensive tris(dimethylamino)cyclopentadienyl zirconium (Zr(NMe₂)₃Cp) are used as Zr sources. Note that each Zr source gas is supplied at 0.5 sccm (reference character a in FIG. 1). In either case, the adsorption probability of a Zr source (Zr precursor) can be increased by lengthening the supply time of the source gas. Initially, the number of fail bits decreases with an increase in the supply time of the source gas. The adsorption probability of the Zr precursor differs, however, between foundations, i.e., between the TiN electrode in the first cycle and the ZrO films in the second cycle or later. Accordingly, optimizing the supply time of the Zr source gas in the first cycle causes the supply time of the Zr source gas in the second cycle or later to become longer than a necessary and sufficient time. When a Zr source resistant to thermal decomposition, such as Zr(NMe₂)₃Cp, is used, there arises the problem of throughput degradation and increase in manufacturing costs, though the number of fail bits does not increase due to an increase in the supply time. On the other hand, when a Zr source susceptible to thermal decomposition, such as widely used TEMAZ, is used, an increase in the supply time causes impurities in the ZrO film to increase, and consequently, the number of fail bits increases once again. In addition, the ZrO film may in some cases become thicker than a designed value due to a thermal decomposition reaction and, in extreme cases, an electrode in a form of cylinder may be blocked up. Conventionally, conditions for the least number of fail bits are determined empirically. Accordingly, in the conventional example illustrated in FIG. 2, the supply time is set to 120 seconds for TEMAZ or to 180 seconds for Zr(NMe₂)₃Cp.

In contrast, in an exemplary embodiment of the present invention, the supply time of the Zr source gas in the first cycle is lengthened to increase the adsorption probability of the Zr precursor, thereby forming a uniform ZrO film (a first layer) in the first cycle. Since the surface to be adsorbed is changed to ZrO in the second cycle or later, the supply time can be shortened to suppress an increase in the number of fail bits in a capacitor dielectric film leak test and reduce the amount of the Zr source to be used.

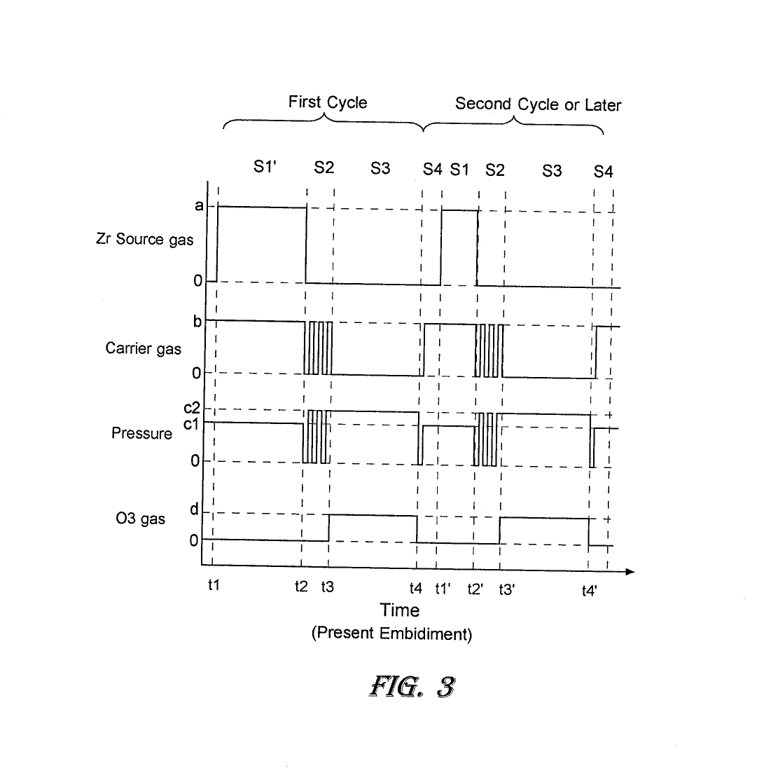

FIG. 3 is a schematic view illustrating a film-forming sequence according to one example of the present invention. The film-forming sequence differs from that of the conventional example illustrated in FIG. 1 in that the Zr source gas supplying step (S1′) in the first cycle is longer in time than the Zr source gas supplying step (S1) in the first cycle of the conventional example. Specifically, if TEMAZ is used in the first cycle, the source gas of TEMAZ is supplied at 0.5 to 1.0 sccm for 300 seconds along with a 10 slm of a carrier gas to carry out the step (S1′) of adsorbing a Zr precursor onto an underlying TiN lower electrode. An inert gas, such as nitrogen gas or argon gas, can be used as the carrier gas. Next, the supply of the Zr source gas is stopped to carry out a step (S2) of performing purge/vacuuming. Next, an ozone (O₃) gas having a concentration of 200 to 300 g/Nm³ is supplied for 300 seconds to carry out a step (S3) of oxidatively decomposing the Zr precursor. Next, the supply of the ozone gas is stopped to carry out a step (S4) of performing purge/vacuuming. Note that if the source gas of TEMAZ is continuously supplied for more than 420 seconds, thermal decomposition in a film-forming space that is a chamber of a film-forming apparatus progresses and the ZrO film thickens to a thickness corresponding to two cycles of film formation in the related art. The supply time is therefore preferably not longer than 420 seconds. A supply time of 250 seconds or longer enables the formation of a sufficiently uniform ZrO film. Accordingly, the supply time in the first cycle (hereinafter referred to as “a first supply time”) is preferably 250 to 420 seconds, and more preferably 300 to 350 seconds for TEMAZ. In the case of Zr(NMe₂)₃Cp, the first supply time is preferably 200 to 360 seconds, and more preferably 240 to 300 seconds.

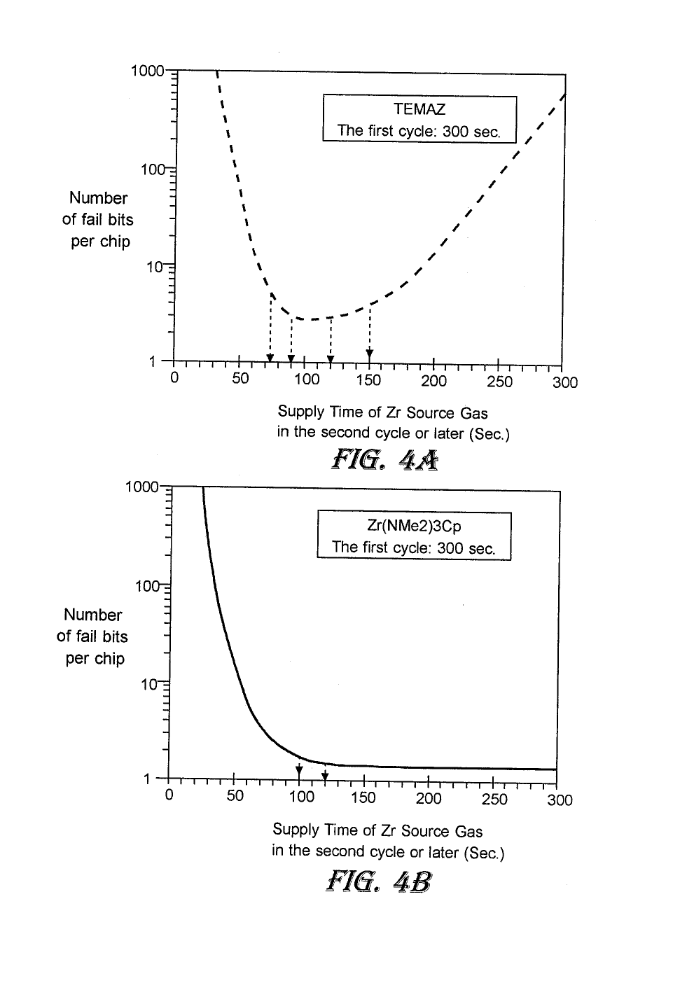

FIG. 4A illustrates the result of determining a variation in the number of fail bits in a capacitor dielectric film leak test by using TEMAZ as the Zr source, setting the first supply time to 300 seconds, and varying a supply time of the source gas in the second cycle or later (hereinafter referred to as “a second supply time”). In addition, FIG. 4B illustrates the result of determining a variation in the number of fail bits in a capacitor dielectric film leak test by using Zr(NMe₂)₃Cp as the Zr source, setting the first supply time to 240 seconds, and varying the second supply time.

It is understood that whereas in the case of TEMAZ (FIG. 4A), the number of fail bits is eight or so in the conventional example even if the supply time is optimized, the number of fail bits is reduced by lengthening the first supply time. It is also understood that the number of fail bits, where the second supply time for TEMAZ is within the range of 75 to 150 seconds, is improved compared with that in the case of the conventional optimized supply time. More preferably, the second supply time for TEMAZ is 90 to 120 seconds.

Whereas the conventional example shows favorable results for a supply time of 180 seconds or longer in the case of Zr(NMe₂)₃Cp (FIG. 4B), the method of the present invention has produced favorable results for a supply time of 120 seconds or longer. From the viewpoint of a reduction in source gas consumption, the supply time is preferably not longer than 180 seconds as in the conventional example, and 150 seconds can suffice as the supply time. A supply time of 100 seconds or longer enables a sufficient reduction in the number of fail bits. Accordingly, the second supply time for Zr(NMe₂)₃Cp is preferably within the range of 100 to 180 seconds, and more preferably within the range of 120 to 150 seconds.

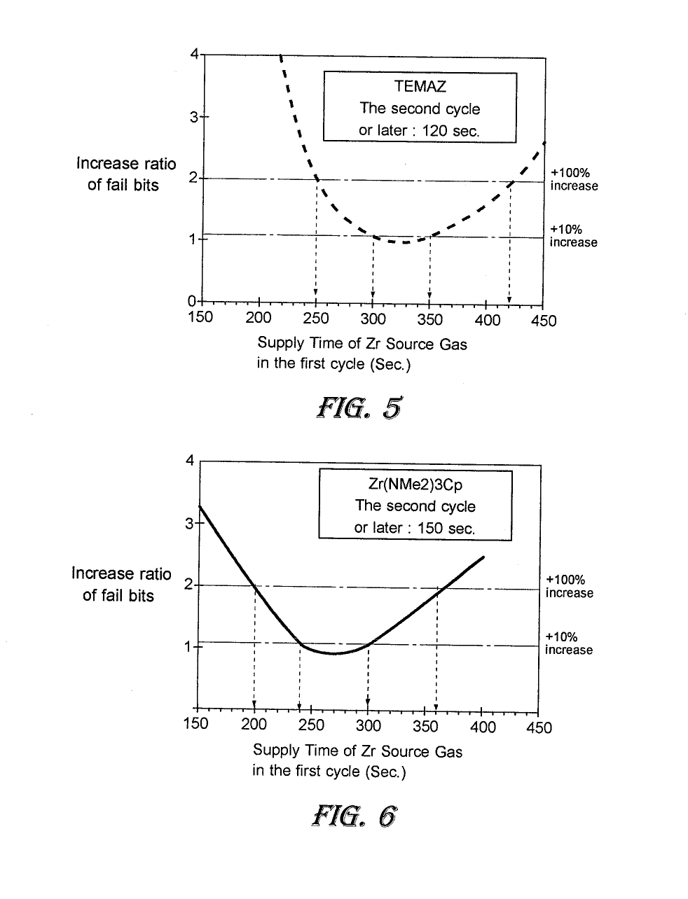

FIGS. 5 and 6 are graphs illustrating the relationship between the first supply time of the Zr source gas and the increase ratio of fail bits per chip in a capacitor dielectric film leak test. FIG. 5 shows a case where TEMAZ is used as the Zr source, whereas FIG. 6 shows a case where Zr(NMe₂)₃Cp is used as the Zr source. The increase ratio of fail bits denoted by the axis of ordinates is defined as (number of fail bits based on the variation of the first supply time of the Zr source gas)/(minimum number of fail bits produced in the first supply time of the Zr source gas).

It is understood that in a case where the Zr source is TEMAZ (FIG. 5):
the graph shows the minimum number of fail bits at a supply time of 330 seconds in the first cycle when the second supply time is kept constant at 120 seconds;
the range of the first supply time in which the number of fail bits settles to a 100% increase is 250 to 420 seconds, and this range is preferable; and
the range of the first supply time in which the number of fail bits settles to a 10% increase is 300 to 350 seconds, and this range is more preferable.

It is also understood that in a case where the Zr source is Zr(NMe₂)₃Cp (FIG. 6):
the graph shows the minimum number of fail bits at a supply time of 270 seconds in the first cycle when the second supply time is kept constant at 150 seconds;
the range of the first supply time in which the number of fail bits settles to a 100% increase is 200 to 360 seconds, and this range is preferable; and
the range of the first supply time in which the number of fail bits settles to a 10% increase is 240 to 300 seconds, and this range is more preferable.

As described above, in the present invention, due to lengthen the first supply time of the Zr source gas, the second supply time of the source gas can be shortened and, thereby enabling improvements in throughputs and reductions in material costs.

The present invention is not limited to the above-described ZrO film formation, but is also applicable if there is a problem with the adsorption ability of a metallic source in the first cycle in a film formation of the corresponding metal compound by an atomic layer deposition including, as one cycle, a step of supplying a metallic source gas to adsorb a metallic source onto a foundation; a step of purging the metallic source gas in a film-forming space; a step of supplying a reactant gas to convert the metallic source into the corresponding metal compound; and a step of purging the reactant gas, and if the reduction of impurities in the film is preferable. Examples of metal atoms in the metallic sources are not limited to zirconium shown in the exemplary embodiment but include aluminum, titanium, and hafnium. In addition, examples of the reactant gas include oxidizing gas such as ozone, oxygen and carbon monoxide, and nitriding gas such as ammonia.

### EXAMPLES

Hereinafter, examples will be cited to describe specific semiconductor device manufacturing methods, though the present invention is not limited to these examples only.

### Example 1

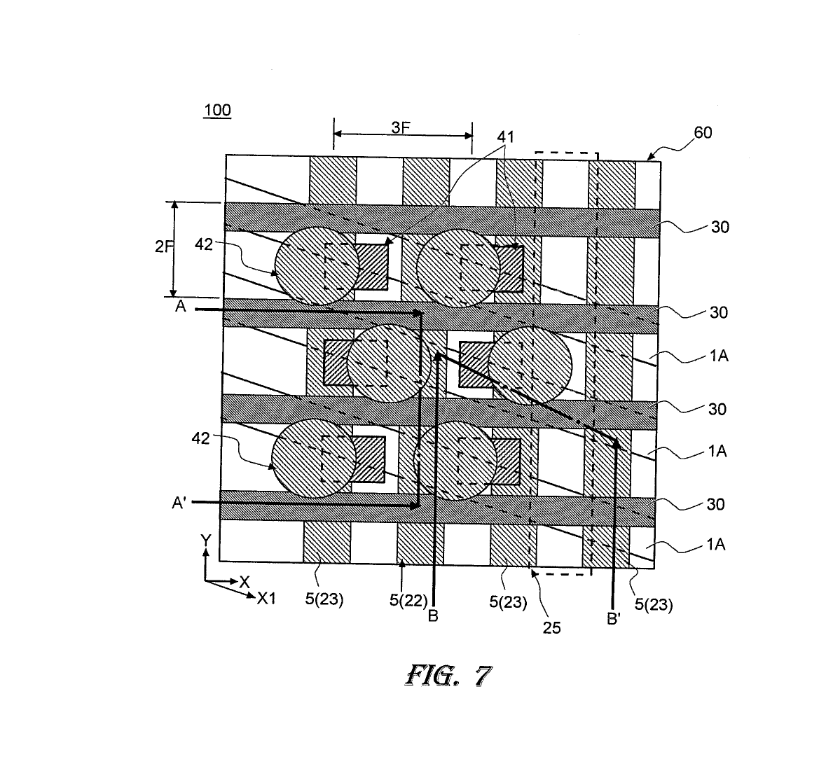

FIG. 7 is a plan view illustrating the configuration of DRAM device 100 according to the present example, and shows a memory cell region of DRAM device 100. FIG. 7 illustrates the layout of an element-isolating region, an element-forming region and buried wiring lines of DRAM device 100. In order to clarify the layout of these components, capacitors located on capacitor contact pads 42, upper metal wiring lines located on the capacitors, and the like are omitted in the figure.

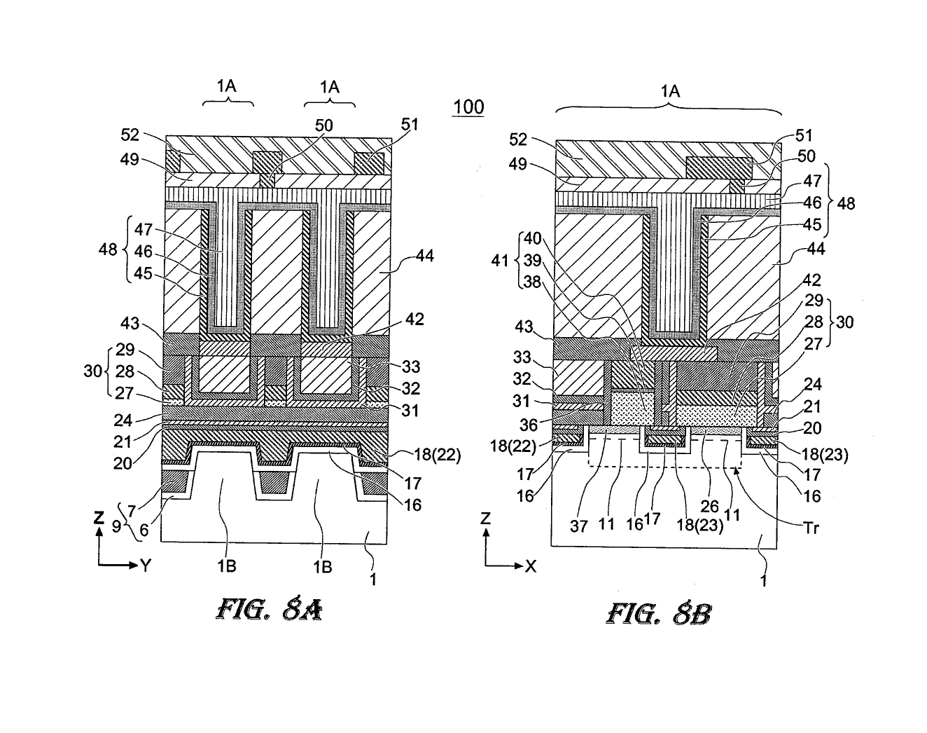

FIGS. 8A and 8B are cross-sectional views illustrating the configuration of DRAM device 100 according to the present example, in which FIG. 8A shows the A-A′ cross section of FIG. 7 and FIG. 8B shows the B-B′ cross section of FIG. 7. Note here that whereas FIG. 8A is a cross-sectional view in a Y direction, FIG. 8B which is a cross-sectional view in an X direction is deviated therefrom in a strict sense. Nonetheless, FIG. 8B is described here as a cross-sectional view in the X direction. It should also be noted that in DRAM device 100 of the present example, a silicon substrate is used for a semiconductor substrate serving as the base of DRAM device 100. In addition, not only a bare semiconductor substrate but also a semiconductor substrate in the process of fabricating a semiconductor device thereon and a semiconductor substrate on which a semiconductor device has been fabricated are generically referred to as a wafer.

As illustrated in FIG. 7, DRAM device 100 includes memory cell region 60, and a peripheral region (not illustrated) in which driving transistors (not illustrated) are disposed outside memory cell region 60. Memory cell region 60 is provided with element-isolating film 9 (hereinafter referred to as “STI” (Shallow Trench Isolation) 9) formed by burying an insulating film in element isolation trenches 4 provided in silicon substrate 1, and element-forming regions 1A (hereinafter referred to as “active regions 1A” in some cases) divided off by STIs 9. FIG. 7 shows the positions of active regions 1A related to capacitor contact pads 42 illustrated in the figure.

A plurality of buried wiring lines 5 include buried word lines 23 extending in the Y direction and buried wiring lines 22 for element isolation, as illustrated in FIG. 7. Buried word lines 23 and buried wiring lines 22 for element isolation have the same structure but differ in functionality. Each buried word line 23 functions as the gate electrode of a memory cell. Buried wiring lines 22 for element isolation functions to isolate elements (transistors) adjacent to the wiring lines by being maintained at a predetermined potential. That is, elements adjacent to each other on the same active region 1A can be isolated from each other by maintaining buried wiring lines 22 for element isolation at a predetermined potential and thereby placing parasitic transistors in an off-state. A plurality of bit lines 30 is disposed at predetermined intervals in a direction perpendicular to buried wiring lines 5 (X direction in FIG. 7).

As illustrated in FIGS. 8A and 8B, buried wiring lines 22 cover the upper surfaces of a plurality of STIs 9 and part of silicon substrate 1. Each memory cell is formed in a region where each buried word line 23 intersects with each active region 1A. A plurality of memory cells is provided in the entire range of memory cell region 60, and a capacitor is connected to each memory cell through capacitor contact pad 42. As illustrated in FIG. 7, capacitor contact pads 42 are disposed at predetermined intervals within memory cell region 60, so as not to overlap with one another. Note that as illustrated in FIG. 7, DRAM device 100 of the present example is configured to have a 6F2 cell layout (F value is the minimum feature size) corresponding to a unit area in which an X-direction pitch and a Y-direction pitch are defined as 3F and 2F, respectively.

DRAM device 100 of the present example is provided with a buried-gate transistor in which buried word line 23 functioning as a gate electrode is completely buried in silicon substrate 1, as illustrated in FIGS. 8A and 8B. The buried-gate transistor is provided in active region 1A fenced by STIs 9 serving as isolation regions of silicon substrate 1. Note that each STI 9 is such that a plurality of insulating films (insulating films 6 and 7 in FIGS. 8A and 8B) are laminated in a trench formed in silicon substrate 1 and extending in an X1 direction shown in FIG. 7. The buried-gate transistor includes gate insulating film 16 covering the inner walls of a trench provided in active region 1 A, intervening layer 17 covering the upper surface and part of the side surfaces of gate insulating film 16, conductive film 18 provided inside intervening layer 17 to serve as buried word line 23, first impurity diffusion layer 26 provided in low-concentration impurity diffusion layer 11 to serve as one of source/drain regions, and second impurity diffusion layer 37 to serve as the other one of the source/drain regions. Low-concentration impurity diffusion layer 11 is provided in the upper portion of each active region 1A, except an area thereof in which gate insulating film 16 is provided, and is a layer in which impurities opposite in conductivity type to conductive impurities contained in abundance in silicon substrate 1 are diffused. The upper surface of conductive film 18 is covered with liner film 20 and buried insulating film 21.

Although only one buried-gate transistor including a buried word line 23 is shown in active region 1A illustrated in FIG. 8B for convenience of description, two buried word lines 23 are disposed between buried wiring lines 22 and two buried-gate transistors are formed with first impurity diffusion layer 26, to which a bit line 30 is connected, shared by the transistors. Several thousand to several hundred thousand buried-gate transistors are disposed in memory cell region 60 of an actual DRAM. In addition, buried wiring line 22 and buried word line 23 are the same in structure, and the Y-direction cross-sectional shape of each buried word line 23 is the same as that of buried wiring line 22 illustrated in FIG. 8A.

As illustrated in FIG. 8A, each buried-gate transistor of the present example has a structure in which part of buried wiring line 22 is buried in the upper surfaces of STIs 9 disposed in the extending direction of buried wiring line 22. That is, buried wiring line 22 is disposed so that the upper-surface height of STI 9 is less than the surface height of silicon substrate 1 between the adjacent STIs 9. Consequently, on the upper surface of silicon substrate 1, filled portions of STIs 9 covered with buried wiring line 22 and saddle-shaped silicon protruding parts 1B to which the bottom surface of buried wiring line 22 connects through gate insulating film 16 are provided. Note that since each buried word line 23 has the same structure as that of buried wiring line 22, the same filled portions of STIs 9 and saddle-shaped silicon protruding parts 1B are also provided below buried word lines 23.

Saddle-shaped silicon protruding parts 1B can be made to function as channels when the potential difference of the silicon protruding parts from source and drain regions exceeds a given threshold. Buried-gate transistors of the present example are saddle-fin transistors including such channel regions as saddle-shaped silicon protruding parts 1B. Applying a saddle-fin transistor as a buried-gate transistor has the advantage of increasing an on-state current.

Next, a configuration of the semiconductor device on and above each of the above-described buried-gate transistors will be described while referring to FIGS. 8A and 8B. Memory cell region 60 of DRAM device 100 is provided with a plurality of memory cells including the above-described buried-gate transistors and capacitors 48. Each capacitor 48 is a cylindrical capacitor and is composed of lower electrode 45, capacitor dielectric film 46 and upper electrode 47. Note that lower electrode 45 is cylindrical and includes an inner wall and an outer wall. The inner wall side is filled with capacitor dielectric film 46 and upper electrode 47. First impurity diffusion layer 26 of each buried-gate transistor is connected to conductive film 27 provided on first impurity diffusion layer 26. Here, conductive film 27 constitutes bit line 30 along with conductive film 28 provided on conductive film 27. The upper surface of bit line 30 is covered with mask film 29, and the side surfaces of bit line 30 are covered with insulating film 31. Second impurity diffusion layer 37 of each buried-gate transistor is connected to lower electrode 45 through capacitor contact plug 41 and capacitor contact pad 42 provided on second impurity diffusion layer 37. Here, capacitor contact plug 41 has a stacked structure in which intervening layer 39 is interposed between conductive film 38 and conductive film 40. The side surfaces of capacitor contact plug 41 are covered with sidewall insulating film 36. In addition, capacitor contact pad 42 is provided in order to secure the alignment margin between capacitor 48 and capacitor contact plug 41. Accordingly, capacitor contact pad 42 need not completely cover the upper surface of capacitor contact plug 41, as illustrated in FIG. 7, but has only to be positioned on capacitor contact plug 41 and connected to at least part thereof.

The side surfaces of bit lines 30, mask films 29 and capacitor contact plugs 41 are covered with first interlayer insulating film 24, insulating film 31, liner film 32 and coated insulating film 33 (hereinafter described as “SOD (Spin On Dielectrics) 33”). In addition, each capacitor contact pad 42 is covered with stopper film 43 for protecting SOD 33. Third interlayer insulating film 44 is provided on stopper film 43. Since cylinder hole 44A penetrating through third interlayer insulating film 44 and stopper film 43 is covered with lower electrode 45, the outer wall of lower electrode 45 has contact with third interlayer insulating film 44 and stopper film 43. The upper surface of third interlayer insulating film 44 is covered with capacitor dielectric film 46, and the upper surface of capacitor dielectric film 46 is covered with upper electrode 47.

Upper electrode 47 is covered with fourth interlayer insulating film 49. Contact plug 50 is provided within fourth interlayer insulating film 49, and upper metal wiring line 51 is provided on the upper surface of fourth interlayer insulating film 49. Upper electrode 47 of capacitor 48 is connected to upper metal wiring line 51 through contact plug 50. Upper metal wiring line 51 and fourth interlayer insulating film 49 are covered with protective film 52.

Note that although as a capacitor of the present example, a description is given of a cylindrical capacitor which utilizes only the inner wall of lower electrode 45 as an electrode, the shape of the capacitor is not limited to cylindrical. For example, the capacitor can be changed to a crown-shaped capacitor which utilizes the inner and outer walls of lower electrode 45 as electrodes. So that it is possible to enlarge the surface area of the electrode by providing the electrode in a direction perpendicular to silicon substrate 1, and forming into a three-dimentional structure. A wiring layer composed of upper metal wiring line 51 and protective film 52 is provided on the capacitor through fourth interlayer insulating film 49. Although in the present example, a single-layer wiring structure composed of a single wiring layer is described by way of example, the wiring layer is not limited to this wiring structure. For example, the single-layer wiring structure can be changed to a multilayer wiring structure composed of a plurality of wiring lines and a plurality of interlayer insulating films.

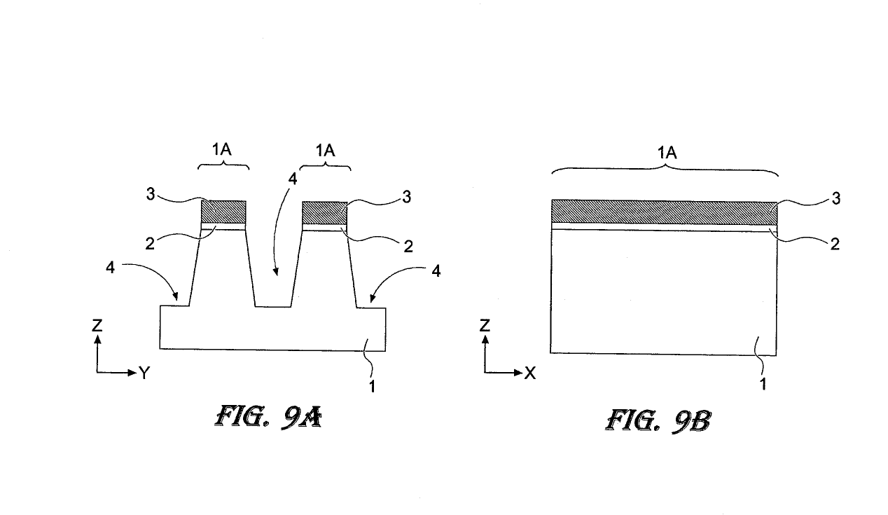

Next, a method for manufacturing DRAM device 100 in the present example will be described with reference to the accompanying drawings. FIG. 9A to FIG. 30B are schematic cross-sectional process diagrams used to describe a method for manufacturing DRAM device 100 according to one example of the present invention, wherein each drawing number suffixed with A corresponds to the A-A′ cross section of FIG. 7, whereas each drawing number suffixed with B corresponds to the B-B′ cross section of FIG. 7.

As illustrated in FIGS. 9A and 9B, sacrificial film 2 which is a silicon oxide film (SiO₂) and mask film 3 which is a silicon nitride film (Si₃N₄) are deposited in order on P-type silicon substrate 1 by a thermal oxidation method and by a thermal CVD (Chemical Vapor Deposition) method, respectively. Next, mask film 3, sacrificial film 2, and silicon substrate 1 are patterned using photolithographic and dry etching techniques to form element isolation trench 4 for dividing off active region 1 A in silicon substrate 1. Upper portions of silicon substrate 1 serving as active regions 1A are covered with mask film 3. Element isolation trenches 4 extend in the X1 direction of FIG. 7.

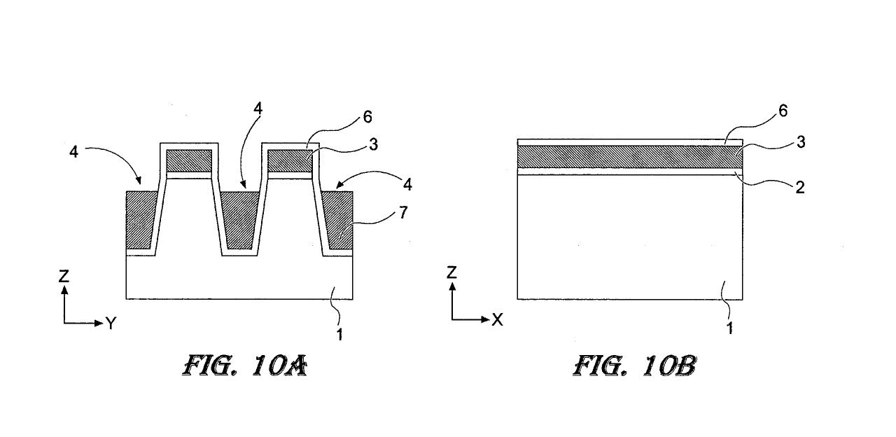

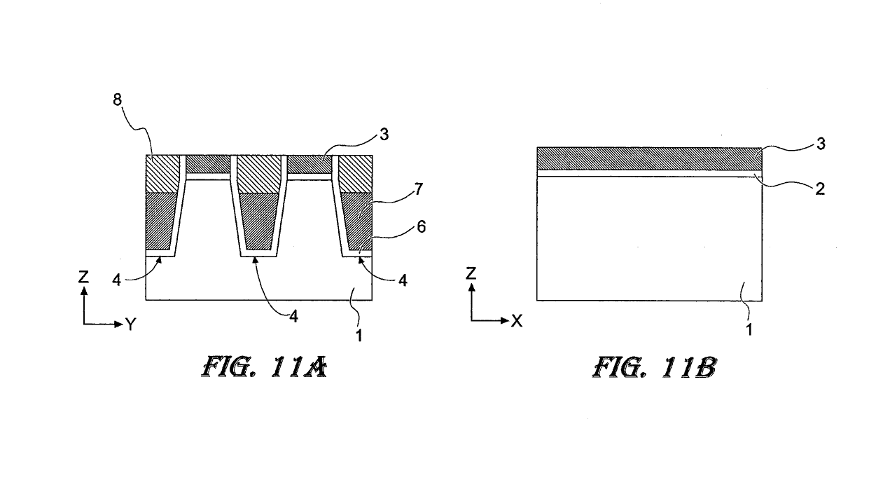

As illustrated in FIGS. 10A and 10B, insulating film 6 which is a silicon oxide film is formed on surfaces of silicon substrate 1 by a thermal oxidation method. At this time, the surface of mask film 3 which is a nitride film is also oxidized. For the sake of simplification, insulating film 6 is shown here in a state of being continuously formed on the surface of mask film 3. Thereafter, insulating film 7 which is a silicon nitride film is deposited by a thermal CVD method, so as to fill element isolation trenches 4, and then etched back to leave over insulating film 7 only within element isolation trenches 4.

As illustrated in FIGS. 11A and 11B, buried film 8 which is a silicon oxide film is deposited by a plasma CVD method, so as to fill element isolation trenches 4. Then, a CMP (Chemical Mechanical Polishing) treatment is performed until mask film 3 formed in FIG. 9 becomes exposed to planarize the surface of buried film 8.

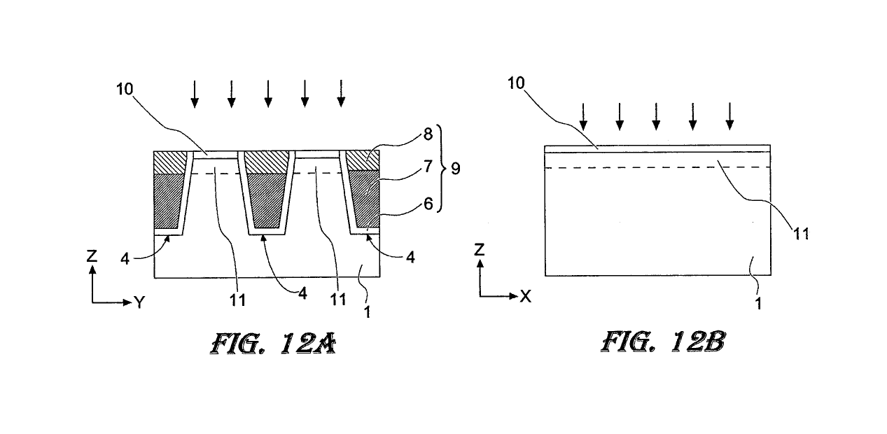

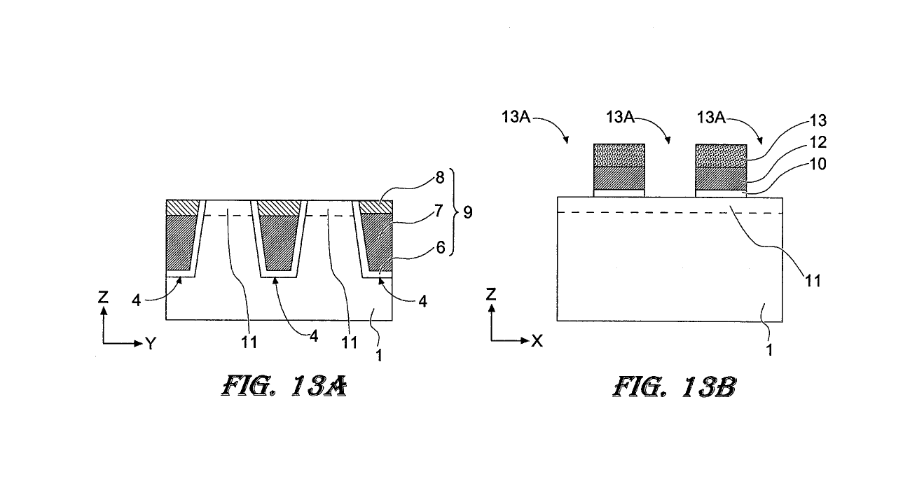

As illustrated in FIGS. 12A and 12B, mask film 3 and sacrificial film 2 are removed by wet etching to expose parts of silicon substrate 1. In addition, buried film 8 on the surface of each element isolation trench 4 is made substantially level with exposed surfaces of silicon substrate 1. As the result of processing described above, STIs 9 composed of insulating films 6 and 7 and buried film 8 are formed. In the method for manufacturing DRAM device 100 according to the present example, line-shaped active regions 1A in memory cell region 60 and peripheral regions (not illustrated) are formed, as illustrated in FIG. 7, as the result of STIs 9 being formed.

After the formation of STIs 9, sacrificial film 10 which is a silicon oxide film is formed on the surface of silicon substrate 1 by a thermal oxidation method. Thereafter, N-type impurities (phosphorous or the like) are implanted with a low concentration into silicon substrate 1 by an ion implantation method to form low-concentration N-type impurity diffusion layer 11. Low-concentration impurity diffusion layer 11 functions as part of source/drain (S/D) regions of a transistor.

As illustrated in FIGS. 13A and 13B, lower mask film 12 which is a silicon nitride film is formed on sacrificial film 10 by a CVD method. In addition, upper mask film 13 which is a carbon film (amorphous carbon film) is deposited on lower mask film 12 by a plasma CVD method. Thereafter, openings 13A are formed in upper mask film 13 and lower mask film 12 to expose parts of silicon substrate 1.

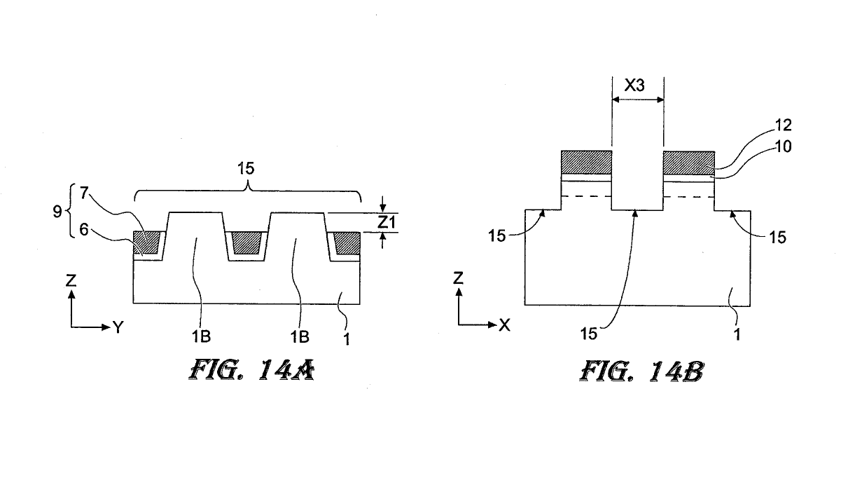

As illustrated in FIGS. 14A and 14B, the parts of silicon substrate 1 exposed out of openings 13A are dry-etched, thereby forming trenches 15, 35 nm in width X3, used to form buried wiring lines 22 and 23. This dry etching is performed by a reactive ion etching (RIE) method based on inductively-coupled plasma (ICP), using tetrafluoromethane (CF₄), sulfur hexafluoride (SF₆), chlorine (Cl₂) and helium (He) as process gases at a bias power of 100 to 300 W and a pressure of 3 to 10 Pa. Trenches 15 are formed as line-shaped patterns extending in the Y direction intersecting with active regions 1A and peripheral regions (not illustrated). When forming trenches 15, STIs 9 are etched deeper than the surfaces of silicon protruding parts 1B. This etching causes saddle-shaped silicon protruding parts 1B, 55 nm in height Z1 from the upper surfaces of STIs 9, to be left over. Each of these saddle-shaped silicon protruding parts 1B functions as a channel region of a transistor.

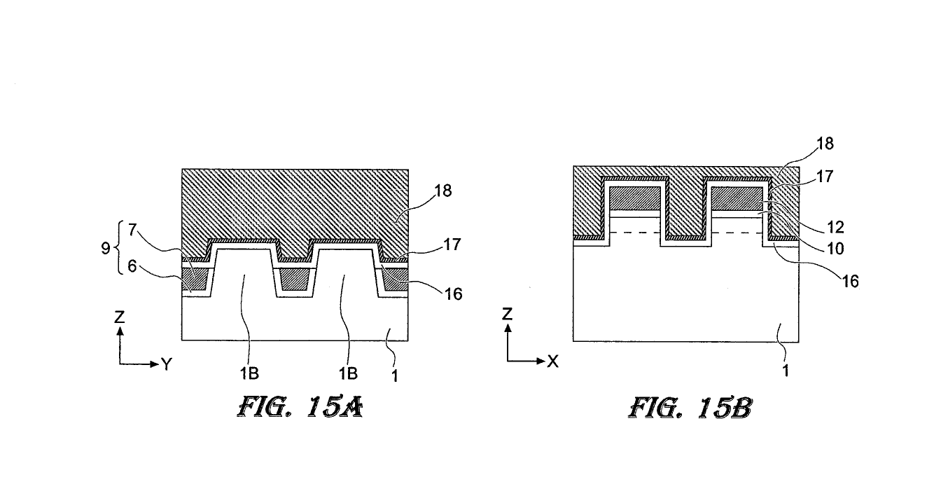

As illustrated in FIGS. 15A and 15B, gate insulating film 16 is formed. As gate insulating film 16, it is possible to use a silicon oxide film or the like formed by a thermal oxidation method. Thereafter, intervening layer 17 which is a titanium nitride (TiN) layer and conductive film (first refractory metal film) 18 which is a tungsten (W) film are deposited in order by a CVD method.

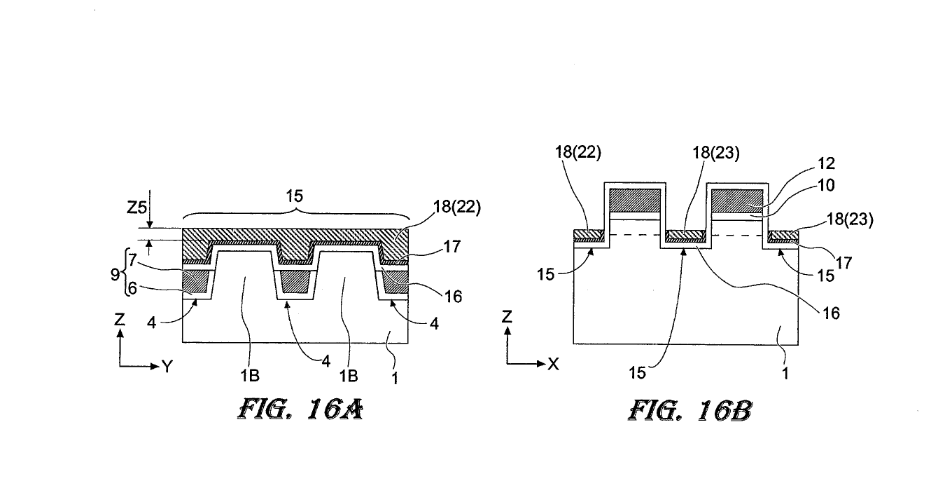

As illustrated in FIGS. 16A and 16B, an unnecessary upper portion of conductive film 18 is removed by dry etching in trenches 15, so that a portion of conductive film 18, approximately 145 nm in thickness Z5 from the upper surfaces of silicon protruding parts 1B, is left over. This dry etching is subject to the condition that no bias is applied to silicon substrate 1 and that the selection ratio of conductive film 18 with respect to intervening layer 17 and gate insulating film 16 is 6 or higher. Accordingly, only conductive film 18 can be easily left over on the bottom of each trench 15, without causing any thickness variations in conductive film 18. Note that the height of conductive film 18 to be left over can be controlled by a dry etching treatment time.

An unnecessary portion of intervening layer 17 is removed by dry etching, so that the intervening layer 17 is left over at a height level with the surface of conductive film 18 on the bottom of each trench 15. This dry etching is subject to the condition that no bias is applied to silicon substrate 1 and that the selection ratio of intervening layer 17 with respect to lower mask film 12 and gate insulating film 16 is 6 or higher. Accordingly, only intervening layer 17 can be easily left over on the bottom of each trench 15. Note that the height of intervening layer 17 to be left over can be controlled by a dry etching treatment time. By this dry etching, it is possible to form buried word lines 23 and buried wiring line 22 composed of intervening layer 17 and conductive film 18 on the bottoms of trenches 15.

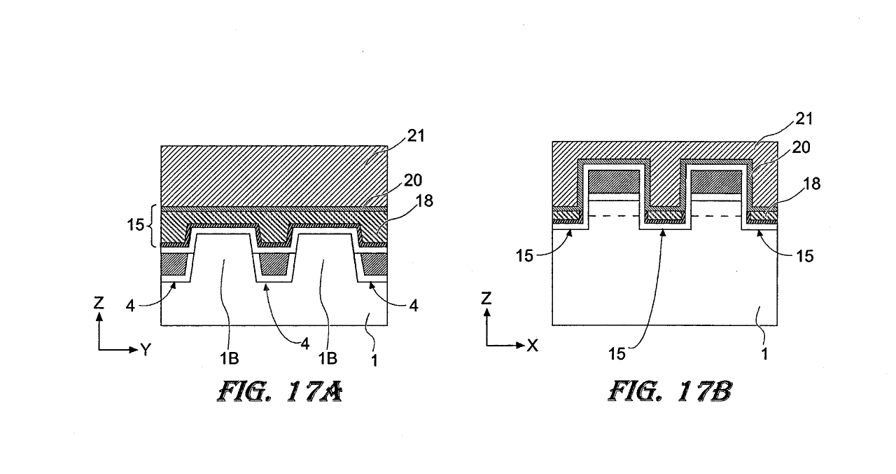

As illustrated in FIGS. 17A and 17B, liner film 20 which is a silicon nitride film is formed by a thermal CVD method, so as to cover the upper surface of left-over conductive film 18 and the inner walls of each trench 15. Next, buried insulating film 21 is deposited on liner film 20. As buried insulating film 21, it is possible to use a silicon oxide film formed by a plasma CVD method, an SOD film which is a coated film, or a laminated film composed thereof. If an SOD film is used, the SOD film is annealing-treated in a high-temperature steam (H₂O) atmosphere after film formation and reformed into a solid-state film.

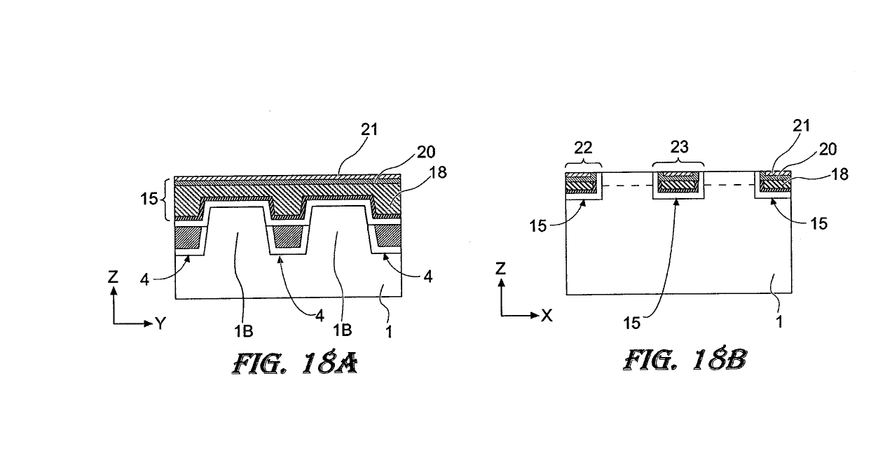

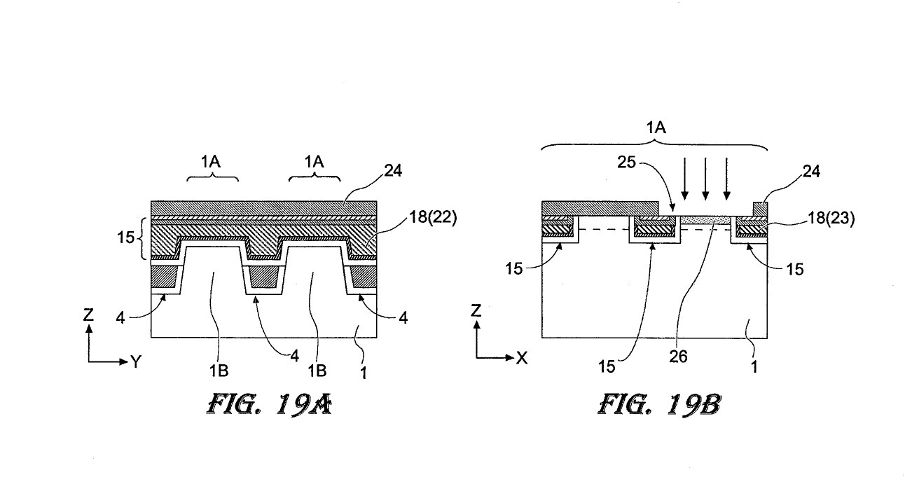

As illustrated in FIGS. 18A and 18B, buried insulating film 21 is removed by a CMP method until liner film 20 becomes exposed. Thereafter, lower mask film 12, sacrificial film 10, and parts of buried insulating film 21 and liner film 20 are removed by etch-back, so that the surface of buried insulating film 21 is substantially level with the surface of silicon substrate 1. Consequently, the upper surfaces of each buried word line 23 and each buried wiring line 22 for element isolation are isolated from each other.

As illustrated in FIGS. 19A and 19B, first interlayer insulating film 24 which is a silicon oxide film based on a plasma CVD method is formed so as to cover silicon substrate 1. Thereafter, part of first interlayer insulating film 24 is removed using photolithographic and dry etching techniques to form bit contact opening 25. As illustrated in FIGS. 7, 19A and 19B, the surface of silicon substrate 1 is exposed in an area where bit contact opening 25 and active region 1A overlap with each other. After the formation of bit contact opening 25, N-type impurities (arsenic or the like) are ion-implanted into the bottom of bit contact opening 25 to form N-type first impurity diffusion layer 26 in the vicinity of the surface of silicon substrate 1. N-type first impurity diffusion layer 26 thus formed functions as one of source/drain regions of a transistor.

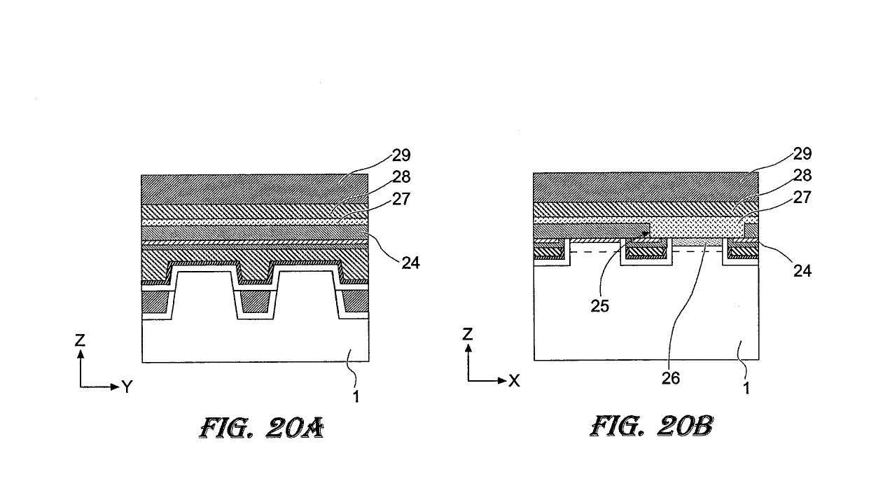

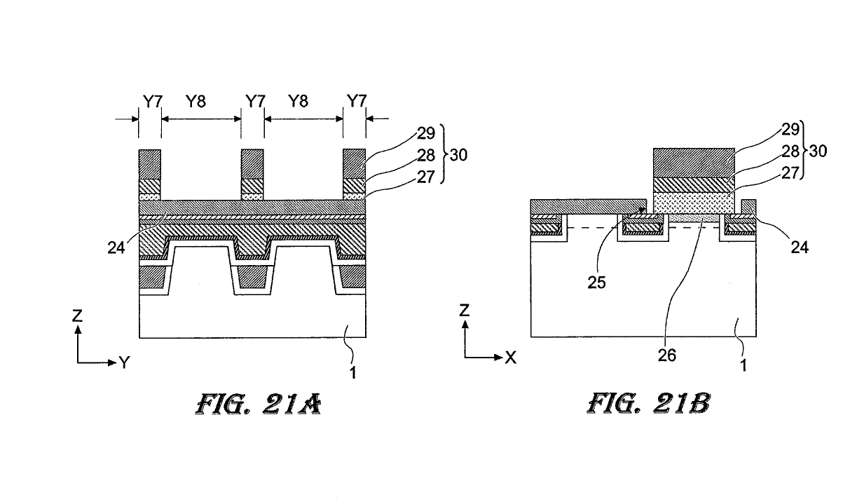

As illustrated in FIGS. 20A and 20B, conductive film (first film) 27 which is a polysilicon film containing N-type impurities (phosphorous or the like) by a thermal CVD method, conductive film (second refractory metal film) 28 which is a tungsten (W) film, and mask film 29 which is a silicon nitride film by a plasma CVD method are deposited in order, so as to cover first impurity diffusion layer 26 and first interlayer insulating film 24.

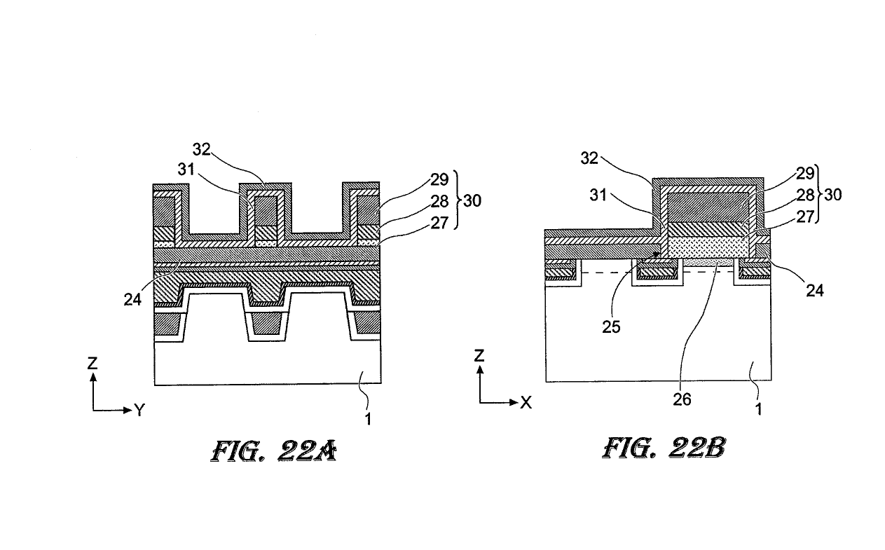

As illustrated in FIGS. 21A and 21B, a laminated film composed of conductive film 27, conductive film 28 and mask film 29 is patterned into a linear shape to form bit line 30 composed of conductive film 27 and conductive film 28. Although Y-direction width Y7 and interval Y8 of bit lines 30 are shown to be different in FIG. 21A, both the width and the interval are set to 50 nm. Note that hereinafter, each bit line 30 may in some cases be referred to as being inclusive of mask film 29 left over on the upper surface of the bit line 30. Each bit line 30 is formed as a pattern extending in the X direction intersecting with buried word lines 23. Conductive film 27 composing the lower layer of each bit line 30 and first impurity diffusion layer 26 (one of source/drain regions) are connected to each other in a surface part of silicon substrate 1 exposed inside bit contact opening 25.

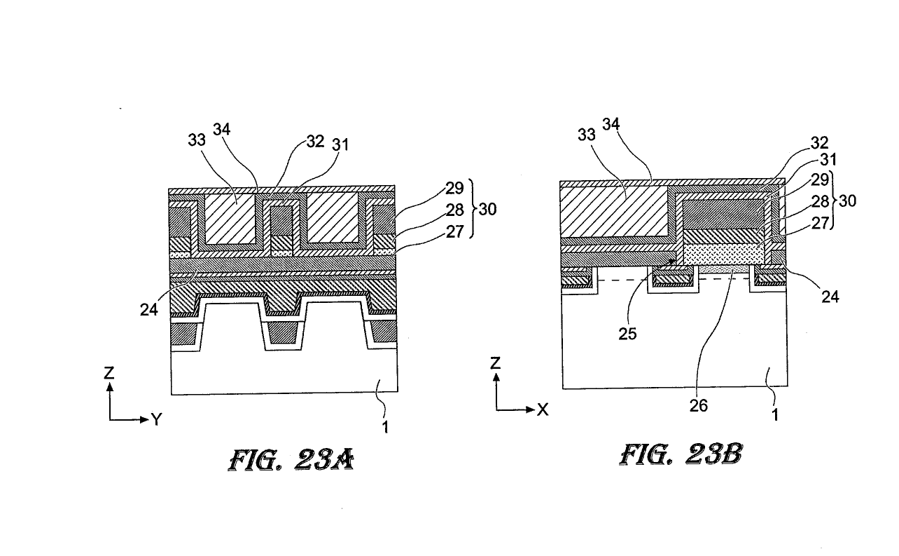

As illustrated in FIGS. 22A and 22B, insulating film 31 which is a silicon nitride film based on a thermal CVD method is formed so as to cover the side surfaces of each bit line 30. Thereafter, liner film 32 which is a silicon nitride film or the like based on a thermal CVD method is formed so as to cover the upper surface of insulating film 31.

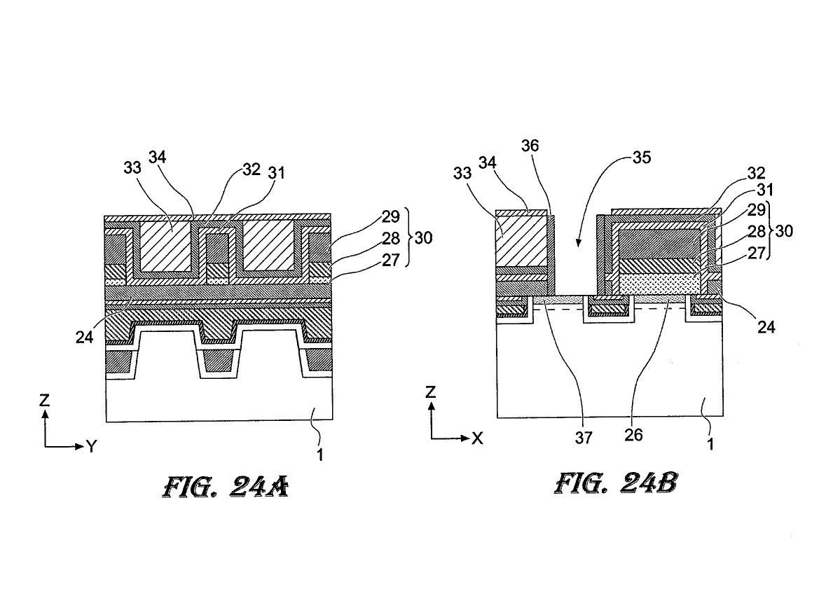

As illustrated in FIGS. 23A and 23B, SOD film 33 which is a coated film is deposited so as to fill the space between adjacent bit lines 30. Thereafter, the SOD film is subjected to anneal-treatment in a high-temperature steam (H₂O) atmosphere and reformed into a solid-state film. Next, SOD film 33 is removed by a CMP method until the upper surface of liner film 32 becomes exposed. Thereafter, second interlayer insulating film 34 which is a silicon oxide film is formed by a plasma CVD method to cover the surface of SOD film 33.

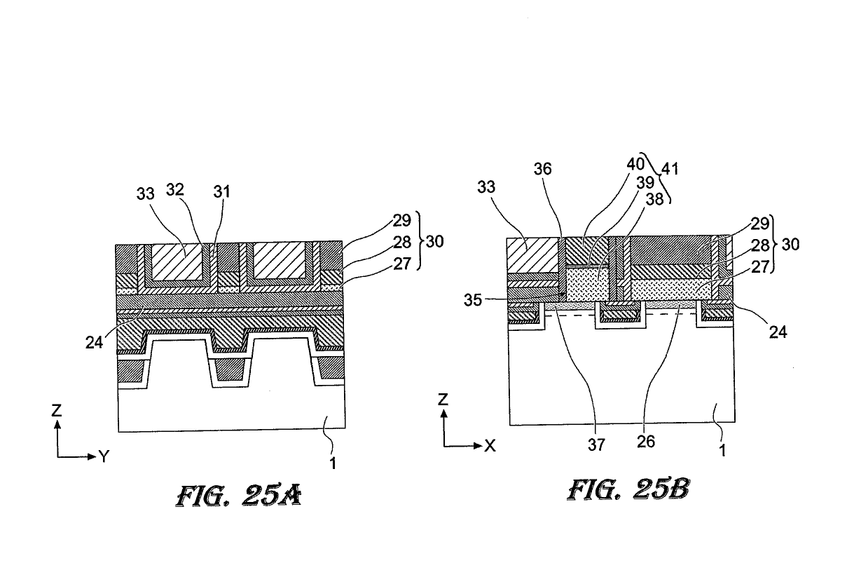

As illustrated in FIGS. 24A and 24B, capacitor contact hole 35 penetrating through second interlayer insulating film 34 and SOD film 33 is formed using photolithographic and dry etching methods. Here, capacitor contact hole 35 is formed by an SAC (Self Alignment Contact) method using above-mentioned insulating film 31 and liner film 32 formed on the side surfaces of each bit line 30 as sidewalls. The surface of silicon substrate 1 is exposed in an area where capacitor contact hole 35 and active region 1A overlap with each other. A silicon nitride film based on a thermal CVD method is formed so as to cover the inner wall of capacitor contact hole 35. Then, the silicon nitride film is etched back to form sidewall (SW) insulating film 36 on the side surfaces of capacitor contact hole 35. After the formation of sidewall insulating film 36, N-type impurities (phosphorous or the like) are ion-implanted into silicon substrate 1 to form N-type second impurity diffusion layer 37 in the vicinity of the surface of silicon substrate 1. N-type second impurity diffusion layer 37 thus formed functions as the source/drain regions of a transistor along with earlier-formed first impurity diffusion layer 26.

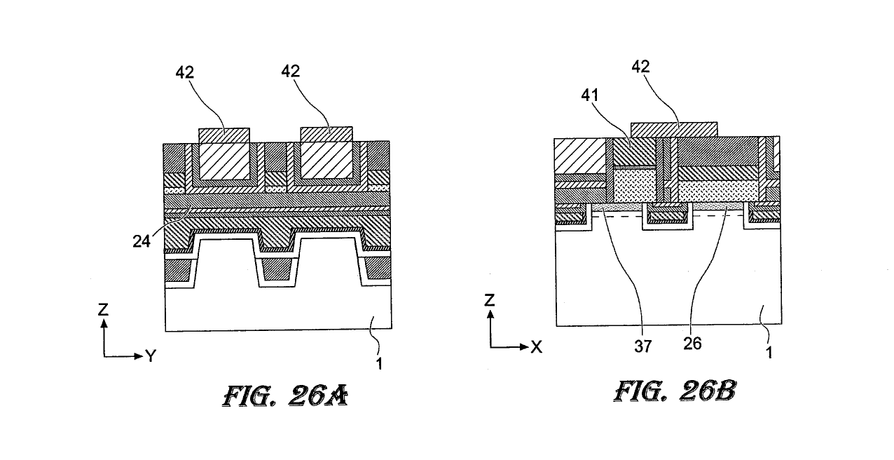

As illustrated in FIGS. 25A and 25B, a polysilicon film containing phosphorous is deposited by a thermal CVD method on the inner side of capacitor contact hole 35. Thereafter, the polysilicon film is etched back so as to leave over the polysilicon film as conductive film (second film) 38 on the bottom of capacitor contact hole 35. Thereafter, a cobalt film is formed on the upper surface of conductive film 38 by a sputtering method and is then silicided to form intervening layer (third film) 39 which is a cobalt silicide (CoSi) layer. Then, conductive film (third refractory metal film) 40 which is a tungsten (W) film is deposited so as to fill capacitor contact hole 35. Next, conductive film 40, second interlayer insulating film 34, liner film 32 and insulating film 31 are removed by a CMP method until the surface of mask film 29 becomes exposed, thereby leaving over conductive film 40 only within capacitor contact hole 35. Consequently, capacitor contact plug 41 composed of stacked films of conductive film 38, intervening layer 39 and conductive film 40.

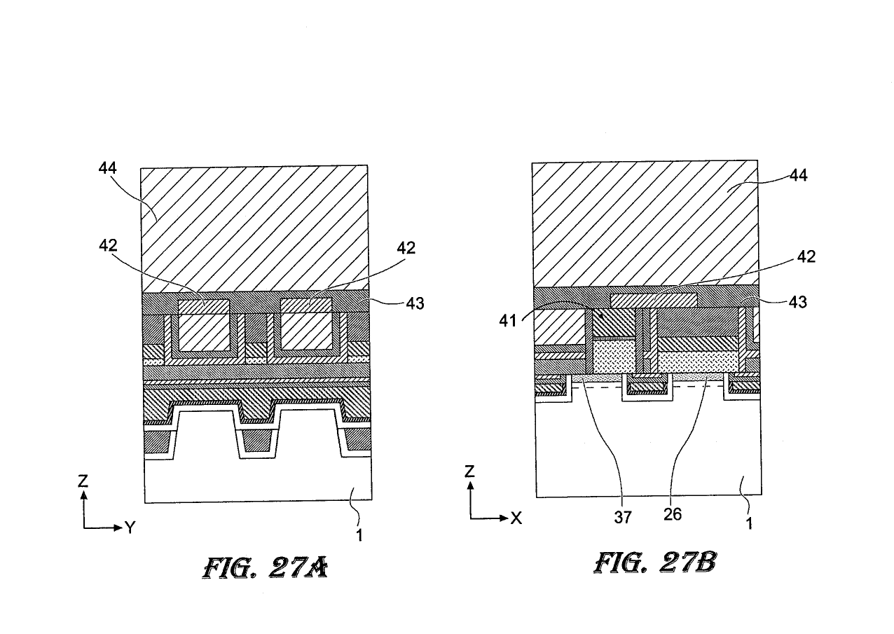

As illustrated in FIGS. 26A and 26B, a laminated film in which a tungsten nitride (WN) film and a tungsten (W) film (fourth refractory metal film) are deposited in order is formed on the upper surface of silicon substrate (wafer) 1 by a sputtering method. Next, the laminated film is patterned using photolithographic and dry etching methods to form capacitor contact pad 42. Here, capacitor contact pad 42 is connected to conductive film 40 constituting capacitor contact plug 41.

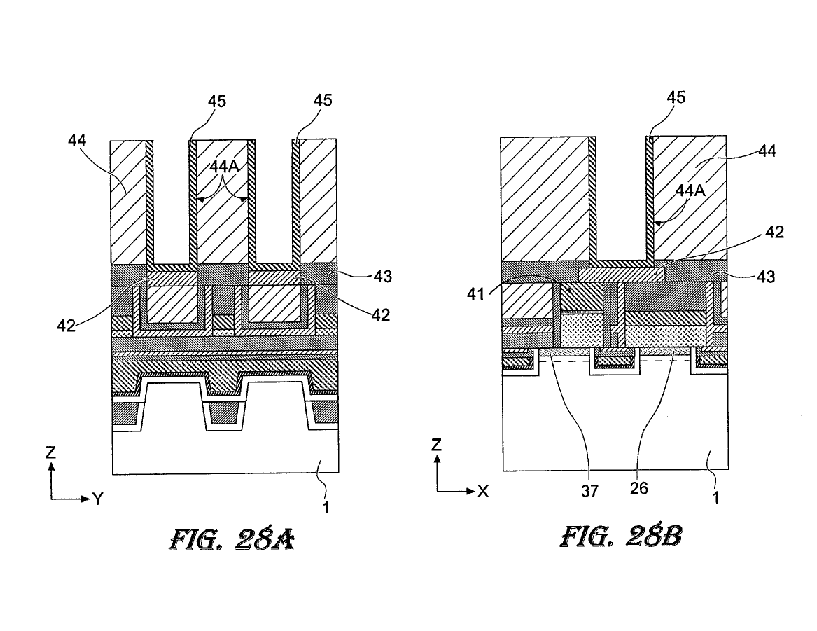

As illustrated in FIGS. 27A and 27B, stopper film 43 which is a silicon nitride film is formed by a thermal CVD method so as to cover the upper surface of each capacitor contact pad 42. Thereafter, third interlayer insulating film 44, which is a silicon oxide film based on a plasma CVD method, is formed on stopper film 43.

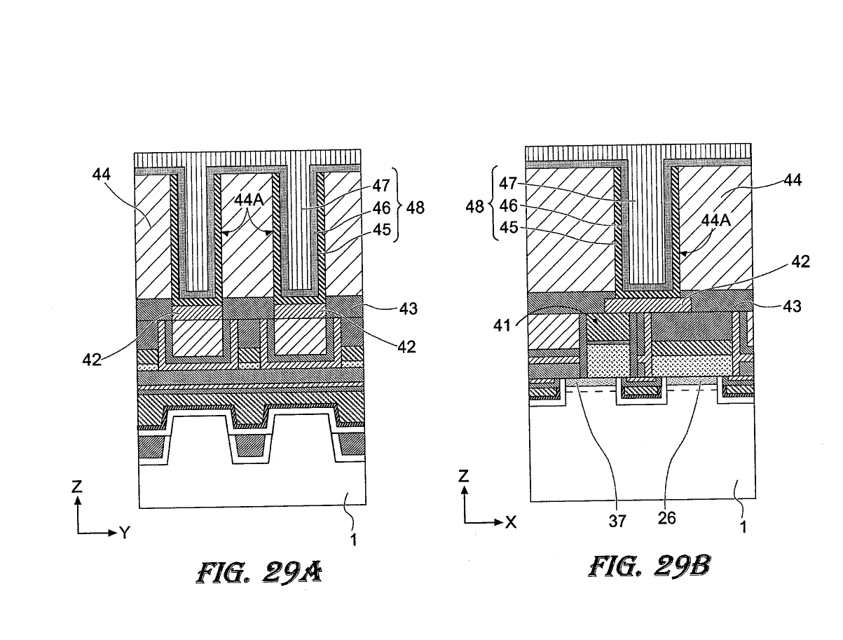

As illustrated in FIGS. 28A and 28B, cylinder hole 44A penetrating through third interlayer insulating film 44 and stopper film 43 is formed using photolithographic and dry etching methods, so as to expose at least part of the upper surface of capacitor contact pad 42. Next, lower electrode 45 of a capacitor is formed by a CVD method using titanium nitride, so as to cover the inner wall of cylinder hole 44A. The bottom surface of lower electrode 45 on the bottom of cylinder hole 44A is connected to capacitor contact pad 42.

As illustrated in FIGS. 29A and 29B, capacitor dielectric film 46 is formed by an ALD method so as to cover the surface of lower electrode 45.

Here, capacitor dielectric film 46 includes at least zirconium oxide (ZrO) formed on a surface of lower electrode 45 by a method according to the present invention, and may include a stacked film in which aluminum oxide (AlO) or hafnium oxide (HfO) is formed on a ZrO film by an ALD method. For example, capacitor dielectric film 46 can be a ZrAlO/ZrO film which is a stacked film composed of a ZrAlO film, which is a laminated film of a ZrO film and an AlO film, and of a ZrO film.

In the present example, a ZrO film was formed as capacitor dielectric film 46 using TEMAZ as a Zr source. Other detailed conditions were adjusted as shown below in the film-forming sequence illustrated in FIG. 3.
TEMAZ flow rate (a): 0.5 to 1.0 sccm

| | | |
|---|---|---|
| Supply time | (the first cycle: t1→t2) | 300 seconds |
| | (the second cycle or later: t1′→t2′) | 120 seconds |

Carrier gas flow rate (b): 10 slm
Pressure (c1): 120 to 140 Pa, (c2): 160 to 200 Pa
O₃ gas concentration (d): 200 to 300 g/Nm³ Supply time: t3→t4=t3′→t4′=300 seconds
Film-forming temperature: 220 to 270° C.
Number of cycles: 45

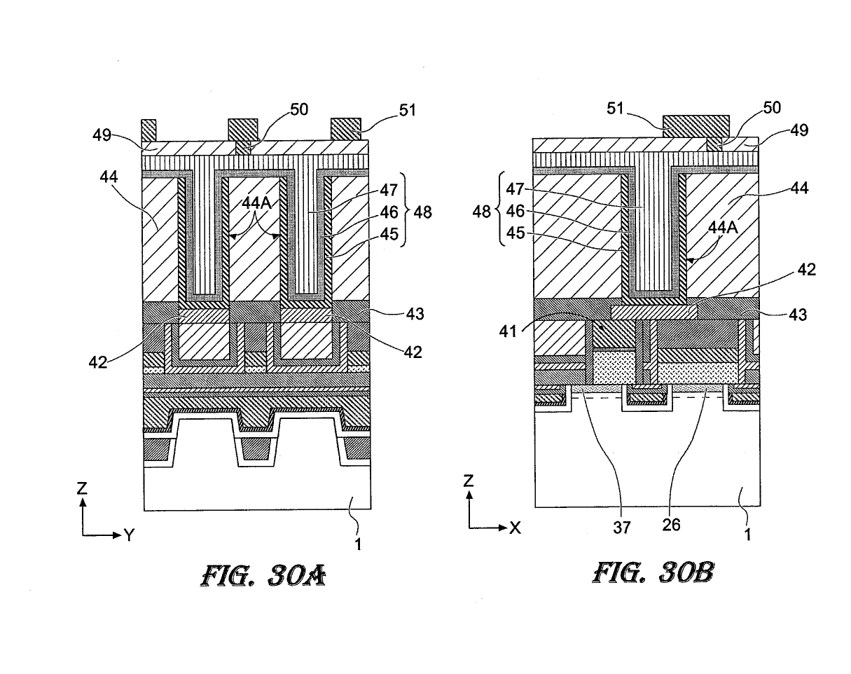

As illustrated in FIGS. 30A and 30B, fourth interlayer insulating film 49, which is a silicon oxide film, is formed by a plasma CVD method so as to cover upper electrode 47. Thereafter, using photolithographic and dry etching methods, a contact hole (not illustrated) is formed in fourth interlayer insulating film 49. Next, the contact hole is filled with tungsten by a CVD method. Then, surplus tungsten on the upper surface of fourth interlayer insulating film 49 is removed by a CMP method to form contact plug 50. Next, a film of aluminum (Al), copper (Cu) or the like is deposited on the upper surface of fourth interlayer insulating film 49, and then the film is patterned to form upper metal wiring line 51. At this time, upper metal wiring line 51 is connected to upper electrode 47 through contact plug 50. Thereafter, protective film 52 for covering upper metal wiring line 51 is formed as illustrated in FIGS. 8A and 8B, thereby bringing the memory cells of DRAM device 100 to completion.

The ALD method according to the present invention can shorten an overall film-forming time which has conventionally been unnecessarily long since film formation is performed using uniform cycles, improve throughputs, and reduce impurity incorporation. Consequently, the present ALD method can be applied to various locations of a semiconductor device in the manufacture thereof.

What is claimed is:

1. A method for manufacturing a semiconductor device, comprising a metal compound film formation process based on an atomic layer deposition, the atomic layer deposition comprising, as one cycle:
supplying a source gas containing a metallic source to adsorb the metallic source onto a foundation;
purging the source gas;
supplying a reactant gas to convert the metallic source into a corresponding metal compound; and
purging the reactant gas,
wherein a supply time of the source gas in a first cycle is longer than a supply time of the source gas in a second cycle or later.

2. The method as claimed in claim 1, wherein the supply time of the source gas in the first cycle is longer than the supply time of the source gas in each of the second cycle or later cycle.

3. The method as claimed in claim 1, wherein the first cycle is to deposit a first layer on a material as the foundation inferior in adsorption ability with respect to the metallic source to the first layer and the second cycle is to deposit a second layer on the first layer.

4. The method as claimed in claim 1, wherein supplying the reactant gas includes supplying an oxidizing gas as the reactant gas to form a metal oxide film by repeating a plurality of cycles.

5. The method as claimed in claim 4, wherein the metallic source comprises zirconium as a metallic element.

6. The method as claimed in claim 5, wherein the metallic source is tetrakis(ethyl-methyl-amino) zirconium.

7. The method as claimed in claim 6, wherein the supply time of the source gas in the first cycle is 250 to 420 seconds and the supply time of the source gas in the second cycle or later is 75 to 150 seconds.

8. The method as claimed in claim 7, wherein the supply time of the source gas in the first cycle is 300 to 350 seconds and the supply time of the source gas in the second cycle or later is 90 to 120 seconds.

9. The method as claimed in claim 5, wherein the metallic source is tris(dimethylamino)cyclopentadienyl zirconium.

10. The method as claimed in claim 9, wherein the supply time of the source gas in the first cycle is 200 to 360 seconds and the supply time of the source gas in the second cycle or later is 100 to 180 seconds.

11. The method as claimed in claim 10, wherein the supply time of the source gas in the first cycle is 240 to 300 seconds and the supply time of the source gas in the second cycle or later is 120 to 150 seconds.

12. The method as claimed in claim 4, wherein the supply time of the source gas is the same in each of the second cycle or later.

13. The method as claimed in claim 4, wherein the oxidizing gas is an ozone gas.

14. The method as claimed in claim 4, wherein the material inferior in adsorption ability with respect to the metallic source is an electrode comprising titanium nitride.

15. The method as claimed in claim 14, wherein the electrode comprising titanium nitride is a lower electrode of a capacitor, and the metal oxide film is at least part of a capacitor dielectric film of the capacitor.

16. The method as claimed in claim 14, wherein the lower electrode has a cylindrical shape and the metal oxide film is formed at least on an inner wall of the lower electrode.

17. The method as claimed in claim 14, wherein the lower electrode has a cylindrical shape and the metal oxide film is formed on inner and outer walls of the lower electrode.

18. A method for manufacturing semiconductor device comprising forming an insulating film by an atomic layer deposition method,
wherein the atomic layer deposition method includes supplying a source gas in forming the insulating film,
wherein the source gas in a first cycle is supplied for a first supplying time, thereafter the source gas is supplied for a second supplying time, and
wherein the first supplying time is longer than the second supplying time.

19. The method as claimed in claim 18, wherein the source gas comprises tetrakis(ethyl-methyl-amino) zirconium, the first supply time is 250 to 420 seconds, and the second supply time is 75 to 150 seconds.

20. The method as claimed in claim 18, wherein the source gas comprises tris(dimethylamino)cyclopentadienyl zirconium, the first supply time is 200 to 360 seconds, and the second supply time is 100 to 180 seconds.
